(19) United States
(12) Patent Application Publication
(10) Pub. No.: US 2004/0164420 A1
(43) Pub. Date: Aug. 26, 2004

(54) Sputtering target compositions, and methods of inhibiting copper diffusion into a substrate

(76) Inventors: Jianxing Li, Spokane, WA (US); Stephen Turner, Moon Township, PA (US); Lijun Yao, Niigata (JP)

Correspondence Address: WELLS ST. JOHN P.S., 601 W. FIRST AVENUE, SUITE 1300, SPOKANE, WA, 99201, US

(21) Appl. No.: 10/783,247

(22) Filed: Feb. 19, 2004

Related U.S. Application Data
(62) Division of application No. 10/297,001, filed on Nov. 26, 2002.
Application No. 10/297,001 is a 371 of international application No. PCT/US01/17996, filed on May 31, 2001.
(60) Provisional application No. 60/225,518, filed on Aug. 15, 2000.

(51) Int. Cl. H01L 23/48; H01L 29/40; H01L 21/3205

(52) U.S. Cl. 257/763; 257/762; 438/687

(57) ABSTRACT

The invention described herein relates to new titanium-comprising materials which can be utilized for forming titanium alloy sputtering targets. The titanium alloy sputtering targets can be reactively sputtered in a nitrogen-comprising sputtering atmosphere to form an alloy TiN film, or alternatively in a nitrogen-comprising and oxygen-comprising sputtering atmosphere to form an alloy TiON thin film. The thin films formed in accordance with the present invention can have a non-columnar grain structure, low electrical resistivity, high chemical stability, and barrier layer properties comparable to those of TaN for thin film Cu barrier applications. Further, the titanium alloy sputtering target materials produced in accordance with the present invention are more cost-effective for semiconductor applications than are high-purity tantalum materials and have superior mechanical strength suitable for high-power sputtering applications.

### TECHNICAL FIELD

The invention pertains to titanium alloy thin films with improved copper diffusion barrier properties. The invention also pertains to titanium alloy sputtering targets, and additionally pertains to methods of inhibiting copper diffusion into substrates.

### BACKGROUND OF THE INVENTION

Integrated circuit interconnect technology is changing from aluminum subtractive processes to copper dual damascene processes. The shift from aluminum and its alloys to copper and its alloys is causing new barrier layer materials, specifically TaN, to be developed. TiN films, which were used in aluminum technologies, could be formed by, for example, reactively sputtering a titanium target in a nitrogen-comprising sputtering gas atmosphere. TiN films are reportedly poor barrier layers relative to copper in comparison to TaN because the diffusivity of copper atoms through TiN films is too high.

The problems associated with TiN barrier layers are described with reference to FIGS. 1 and 2. Specifically, FIG. 1 illustrates a preferred barrier layer construction, and FIG. 2 illustrates problems associated with TiN barrier layers.

Referring initially to FIG. 1, a semiconductor wafer fragment 10 is illustrated. Wafer fragment 10 comprises a substrate 12 which can comprise, for example, monocrystalline silicon. To aid in interpretation of the claims that follow, the terms “semiconductive substrate” and “semiconductor substrate” are defined to mean any construction comprising semiconductive material, including, but not limited to, bulk semiconductive materials such as a semiconductive wafer (either alone or in assemblies comprising other materials thereon), and semiconductive material layers (either alone or in assemblies comprising other materials). The term “substrate” refers to any supporting structure, including, but not limited to, the semiconductive substrates described above.

An insulative layer 14 is formed over substrate 12. Insulative layer 14 can comprise, for example, silicon dioxide or borophosphosilicate glass (BPSG). Alternatively, layer 14 can comprise fluorinated silicon dioxide having a dielectric constant less than or equal to 3.7, or a so-called “low-k” dielectric material. In particular embodiments, layer 14 can comprise an insulative material having a dielectric constant less than or equal to 3.0.

A barrier layer 16 is formed to extend within a trench in insulative material 14, and a copper-containing seed layer 18 is formed on barrier layer 16. Copper-containing seed layer 18 can be formed by, for example, sputter deposition from a high purity copper target, with the term “high purity” referring to a target having at least 99.995% purity (i.e., 4N5 purity). A copper-containing material 20 is formed over copper-containing seed layer 18, and can be formed by, for example, electrochemical deposition onto seed layer 18. Copper-containing material 20 and seed layer 18 can together be referred to as a copper-based layer or copper-based mass.

Barrier layer 16 is provided to prevent copper diffusion from materials 18 and 20 into insulative material 14. It has been reported that prior art titanium materials are not suitable as barrier layers for preventing diffusion of copper. Problems associated with prior art titanium-comprising materials are described with reference to FIG. 2, which shows the construction 10 of FIG. 1, but which is modified to illustrate specific problems that can occur if either pure titanium or titanium nitride are utilized as barrier layer 16. Specifically, FIG. 2 shows channels 22 extending through barrier layer 16. Channels 22 can result from columnar grain growth associated with the titanium materials of barrier layer 16. Channels 22 effectively provide paths for copper diffusion through a titanium-comprising barrier layer 16 and into insulative material 14. The columnar grain growth can occur during formation of a Ti or TiN layer 16, or during high temperature processing subsequent to the deposition. Specifically, it is found that even when prior art titanium materials are deposited without columnar grain, the materials can fail at temperatures in excess of 450° C.

In an effort to avoid the problems described with reference to FIG. 2, there has been a development of non-titanium barrier materials for diffusion layer 16. Among the materials which have been developed is tantalum nitride (TaN). It is found that TaN can have a close to nanometer-sized grain structure and good chemical stability as a barrier layer for preventing copper diffusion. However, a difficulty associated with TaN is that the high cost of tantalum can make it difficult to economically incorporate TaN layers into semiconductor fabrication processes. Alternatively, we have found that many titanium alloys can have superior mechanical properties compared to tantalum; both in the sputtering target and sputtered film; thus making them suitable for high-power applications.

Titanium alloys are a lower cost material than tantalum. Accordingly, it is possible to reduce materials cost for the microelectronics industry relative to utilization of copper interconnect technology if methodology could be developed for utilizing titanium-comprising materials, instead of tantalum-comprising materials, as barrier layers for inhibiting copper diffusion. It is therefore desirable to develop new titanium-comprising materials which are suitable as barrier layers for impeding or preventing copper diffusion. The titanium comprising materials can be of any purity, but are preferably high purity; with the term “high purity” referring to a target having at least 99.95% purity (i.e., 3N5 purity).

### SUMMARY OF THE INVENTION

The invention described herein relates to new titanium-comprising materials which can be utilized for forming titanium alloy sputtering targets. These sputtering targets can be used to replace tantalum-comprising targets due to their high-strength and resulting film properties. Specifically, in certain embodiments, the titanium alloy sputtering targets can be used to form barrier layers for Cu applications. The titanium alloy sputtering targets can be reactively sputtered in a nitrogen-comprising sputtering gas atmosphere to form titanium alloy nitride film, or alternatively in a nitrogen-comprising and oxygen-comprising atmosphere to form titanium alloy oxygen nitrogen thin film. The thin films formed in accordance with the present invention can have a non-columnar grain structure, low electrical resistivity, high chemical stability, and barrier layer properties comparable to those of TaN. Further, the titanium alloy sputtering target materials produced in accordance with the present invention are more cost-effective for semiconductor applications than are high-purity tantalum materials.

In one aspect, the invention encompasses a sputtering target comprising Ti and one or more alloying elements which have a standard electrode potential of less than −1.0 volt. To the extent that Zr, Al or Si are present, it can be desirable that they are not present in the form of binary alloys with Ti (with binary complexes being TiZr, TiAl and TiSi). Additionally, if a target comprises a binary alloy of TiZr, it can be desirable that Zr be present in a range of from 32-38 atom % or a range of 12-18 atom %; or it can be desired to have the Zr present in any amount from greater than 0 atom % to less than 50 atom % in Cu barrier applications. In embodiments in which the sputtering target comprises multiple alloying elements, all of the alloying elements can have the standard electrode potential of less than −1.0 volt, or less than all of the alloying elements can have the standard electrode potential of less than −1.0 volt

In another aspect, the invention encompasses a method of inhibiting copper diffusion into a substrate. A first layer comprising titanium and one or more alloying elements which have a standard electrode potential of less than −1.0V is formed over the substrate. A copper-based layer is then formed over the first layer and separated from the substrate by the first layer. The first layer inhibits copper diffusion from the copper-based layer to the substrate.

In yet another aspect, the invention encompasses a sputtering target comprising Ti and one or more elements which have melting temperatures greater than or equal to 2400° C. In embodiments in which the sputtering target comprises multiple alloying elements in addition to Ti, all of the elements other than Ti can have the melting temperature greater than or equal to 2400° C., or less than all of the elements other than Ti can have the melting temperature greater than or equal to 2400° C.

In yet another aspect, the invention encompasses a sputtering target comprising Ti and one or more alloying elements with differences in atomic radii relative to Ti of at least 8%, or at least 10%, and in some applications at least 20%. In embodiments in which the sputtering target comprises multiple alloying elements, all of the alloying elements can have the difference in atomic radii relative to Ti of at least 8%, or less than all of the alloying elements can have the difference in atomic radii relative to Ti of at least 8%.

For purposes of interpreting this disclosure and the claims that follow, a “titanium-based” material is defined as a material in which titanium is a majority element, and an “alloying element” is defined as an element that is not a majority element in a particular material. A “majority element” is defined as an element which is present in larger concentration than any other element of a material. A majority element can be a predominate element of a material, but can also be present as less than 50% of a material. For instance, titanium can be a majority element of a material in which the titanium is present to only 30%, provided that no other element is present in the material to a concentration of greater than or equal to 30%. The other elements present to concentrations of less than or equal to 30% would be “alloying elements.” Frequently, titanium-based materials described herein will contain alloying elements at concentrations of from 0.001 atom % to 50 atom %. The percentages and concentrations referred to herein are atom percentages and concentrations, except, of course, for any concentrations and percentages specifically indicated to be other than atom percentages or concentrations.

Additionally, for purposes of interpreting this disclosure and the claims that follow a “copper-based” material is defined as a material in which copper is the majority element.

### BRIEF DESCRIPTION OF THE DRAWINGS

Preferred embodiments of the invention are described below with reference to the following accompanying drawings.

FIG. 1 is a diagrammatic, cross-sectional view of a prior art semiconductor wafer fragment illustrating a conductive copper material separated from an insulative material by a barrier layer.

FIG. 2 is a view of the FIG. 1 prior art wafer fragment illustrating problems which can occur when utilizing prior art Ti-containing materials as the barrier layer.

FIG. 3 is a diagrammatic, cross-sectional view of a semiconductor wafer fragment at a preliminary step of a method of the present invention.

FIG. 4 is a view of the FIG. 3 wafer fragment shown at a processing step subsequent to that of FIG. 4.

FIG. 5 is a view of the FIG. 3 wafer fragment shown at a processing step subsequent to that of FIG. 4.

FIG. 6 is a view of the FIG. 3 wafer fragment shown at a processing step subsequent to that of FIG. 5.

FIG. 7 is an expanded view of a portion of the FIG. 5 wafer fragment.

FIG. 8 is a diagrammatic graph illustrating a relative concentration of a material “Q” relative to a copper-containing layer, TiQ layer and SiO layer along an axis shown in FIG. 4.

FIG. 9 is a diagrammatic graph of a relative concentration of a material “Q” relative to a copper-containing layer, TiQ layer and SiO layer along an axis shown in FIG. 5.

FIG. 10 is a chart showing improvements in mechanical properties of Ti—Zr alloys in comparison to prior art Ta.

FIG. 11 is a diagrammatic, cross-sectional view of an exemplary sputtering target construction.

FIG. 12 is a graph illustrating a Rutherford Back-scattering Spectroscopy (RBS) profile of as-deposited Ti_{0.45}Zr_{0.024}N_{0.52.}

FIG. 13 is an illustration of sheet resistance of Ti_{0.45}Zr_{0.024}N_{0.52}. The Rs spacing is equal to ⅓ sigma, and the shown gradients correspond to 68.99; 67.88; 66.76; 65.65; 64.54; 63.42; 62.31; 61.19; and 60.08.

FIG. 14 is a graph illustrating a Rutherford Back-scattering Spectroscopy profile Ti_{0.45}Zr_{0.024}N_{0.52} after vacuum annealing for 1 hour at from 450° C. to 700° C.

FIG. 15 is a graph illustrating a Rutherford Back-scattering Spectroscopy profile of a TiZrN thin film after stripping Cu layer from a wafer. The TiZrN thin film and Cu layer being initially part of a structure formed in accordance with an exemplary method of the present invention. The illustrated data shows no apparent diffusion of Cu into the TiZrN layer after 5 hours at 700° C.

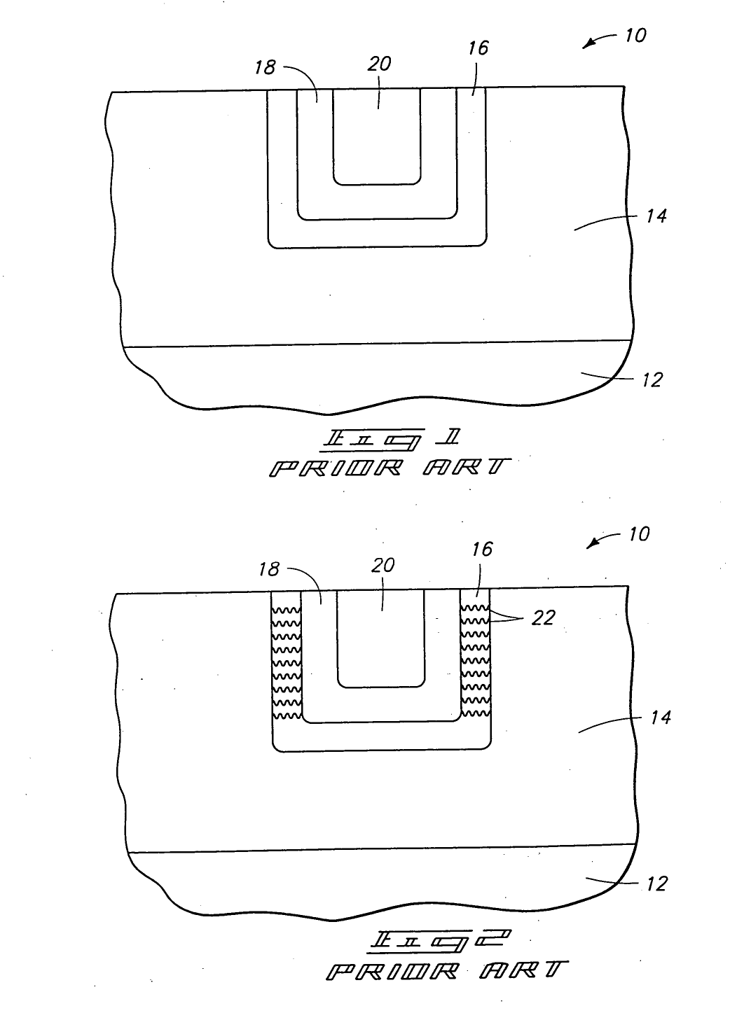

### DETAILED DESCRIPTION OF THE PREFERRED EMBODIMENTS

Exemplary embodiments of the present invention are described with reference to FIGS. 3-9. Referring initially to FIG. 3, a semiconductor wafer fragment 50 is illustrated. Wafer fragment 50 comprises a semiconductive material substrate 52, such as, for example, monocrystalline silicon. An insulative material 54 is formed over substrate 52, and an opening 56 is formed into insulative material 54. Materials 52 and 54 can comprise the same materials as described with reference to the prior art for materials 12 and 14, respectively. Opening 56 can comprise, for example, a trench for formation of copper in a dual damascene process.

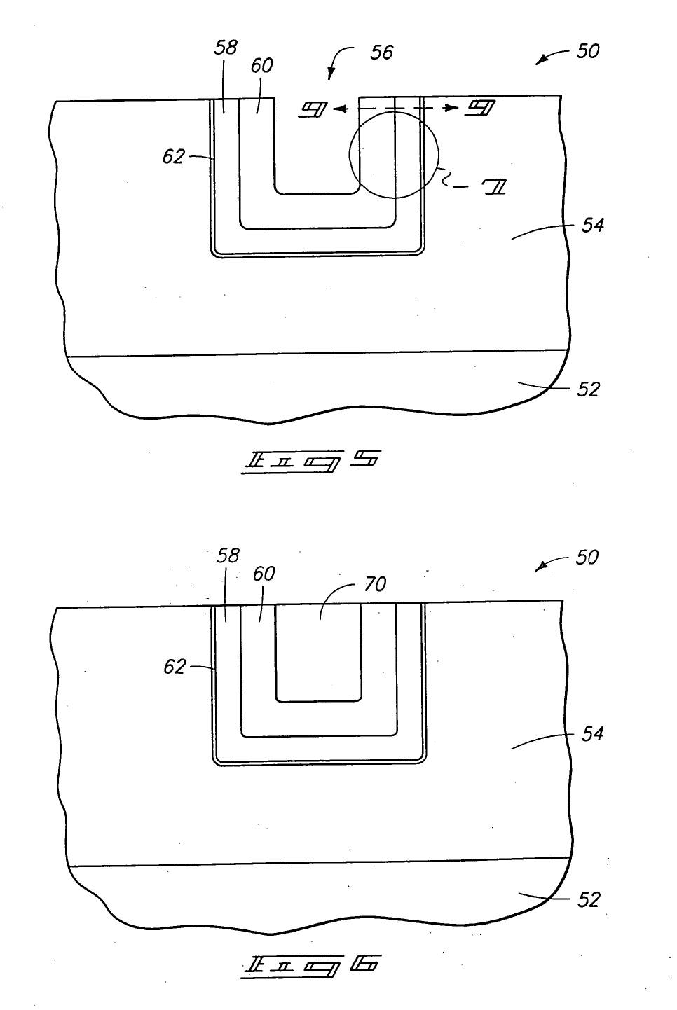

Referring to FIG. 4, a barrier layer 58 is formed over insulative layer 54 and within opening 56. In accordance with the present invention, barrier layer 58 comprises titanium, and is configured to impede diffusion from subsequently-formed copper-based layers into insulative material 54. In one aspect of the invention, barrier layer 58 comprises titanium and one or more elements which have a standard electrode potential (specifically, a standard reduction potential measured with a Cl⁻¹/Cl reference electrode) of less than −1.0V (i.e. more negative than −1.0 volt). Suitable elements can be selected from the group consisting of Al, Ba, Be, Ca, Ce, Cs, Hf, La, Mg, Nd, Sc, Sr, Y, Mn, V, Si and Zr; although in particular embodiments the elements will not include Al, Si, or Zr. Further, barrier layer 58 can consist essentially of the titanium and one or more elements having a standard electrode potential of less than about −1.0V, or can consist of the titanium and one or more elements having a standard electrode potential of less than −1.0V. Barrier layer 58 can also comprise one or both of nitrogen and oxygen in addition to the Ti and the one or more elements having a standard electrode potential of less than −1.0V. Layer 58 can be considered as a film formed over substrate 54, and in particular embodiments will have a thickness of from about 2 nanometers to about 500 nanometers, and can specifically have a thickness of from about 2 nanometers to about 50 nanometers, or can specifically have a thickness of from about 2 nanometers to about 20 nanometers.

In another aspect of the invention, barrier layer 58 comprises titanium and one or more elements which have a melting temperature of greater than or equal to about 2400° C. Suitable elements can be selected from the group consisting of Nb, Mo, Ta and W. Further, barrier layer 58 can consist essentially of the titanium and one or more elements having a melting temperature of greater than or equal to about 2400° C., or can consist of the titanium and one or more elements having a melting temperature of greater than or equal to about 2400° C. Barrier layer 58 can also comprise one or both of nitrogen and oxygen in addition to the Ti and the one or more elements having a melting temperature of greater than or equal to about 2400° C. Layer 58 can be considered as a film formed over substrate 54, and in particular embodiments will have a thickness of from about 2 nanometers to about 50 nanometers, and can specifically have a thickness of from about 2 nanometers to about 20 nanometers. The elements having a melting temperature of greater than or equal to about 2400° C. can stabilize a titanium alloy due to refractory characteristics of the elements.

One aspect of the materials of the present invention that can be important in maintaining desired small grain sizes in barrier layers and sputtering targets of the present invention is that the elements incorporated into the titanium-comprising targets can have atomic sizes which are more than 8% different than the atomic size of titanium, and preferably more than 10%, or even more than 20% different than the atomic size of titanium. Such difference in atomic size can disrupt a titanium lattice structure, and accordingly impede grain growth within the lattice. A magnitude of difference in grain size between the titanium and the other elements incorporated into barrier layer 58 can effect the amount by which a lattice is disrupted, and accordingly can influence an amount of grain growth occurring at various temperatures. It can therefore be preferable to utilize elements having larger differences in size relative to titanium than atoms having less difference in size relative to titanium. A group of elements having an atomic radii difference relative to titanium of at least 8% is Mn, Fe, Co, Ni and Y; and a group of elements having an atomic radii difference relative to titanium of at least 20% is Be, B, C, La, Ce, Pr, P, S, Nd, Sm, Si, Gd, Dy, Ho, Er, and Yb. It is noted that some of the elements having an atomic radii difference relative to titanium of greater than 8%, or greater than 20%, overlap with the elements having a standard electrode potential of less than −1.0V, and some do not. The present invention encompasses utilizing elements having an atomic radii difference relative to titanium of greater than 8% (or in some applications greater than 20%) in combination with titanium for forming barrier layers, and accordingly comprises sputtering targets comprising titanium and one or more of Si, P, S, Sc, Mn, Fe, Co, Ni, Y, Be, B, C, Mo, La, Ce, Pr, Nd, Sm, Gd, Dy, Ho, Er, and Yb.

In a sense, the invention encompasses alloying elements that fall within three categories: a standard electrode potential of less than about −1 .0V; a melting temperature of greater than or equal to about 2400° C.; or an atomic size which is more than 8% different than the atomic size of titanium. Table 1 lists several exemplary elements that can fall within one or more of such three categories. Table 1 is not an all-inclusive listing of elements that fit within one or more of the three categories.

TABLE 1

| | Atomic | % Atomic radius | Standard Electrode | Melting |
|---|---|---|---|---|
| | Radius | difference from Ti | Potential¹ (Volts) | Point |
| Element | (Å) | (2.00 Å) | (Reaction) | (° C.) |
| Al | 1.82 | −9 | −1.70 (Al³⁺/Al) | 660 |
| B | 1.17 | −41.5 | −1.20 (B³⁺/B) | 2300 |
| Ba | 2.78 | 39 | −3.53 (Ba²⁺/Ba) | 725 |
| Be | 1.4 | −30 | −1.80 (Be²⁺/Be) | 1278 |
| C | 0.91 | −54.5 | 0.14 (C⁴⁺/C) | 3500 |
| Ca | 2.23 | 11.5 | −3.26 (Ca²⁺/Ca) | 839 |
| Ce | 2.7 | 35 | −2.82 (Ce³⁺/Ce) | 795 |
| Co | 1.67 | −16.5 | −0.88 (Co²⁺/Co) | 1495 |
| Cr | 1.85 | −7.5 | −1.37 (Cr²⁺/Cr) | 1857 |
| Cs | 3.34 | 67 | −3.44 (Cs¹⁺/Cs) | 28.5 |
| Dy | 2.49 | 24.5 | −2.27 (Dy³⁺/Dy) | 1412 |
| Er | 2.45 | 22.5 | −2.51 (Er³⁺/Er) | 1522 |
| Fe | 1.72 | −14 | −1.10 (Fe²⁺/Fe) | 1535 |
| Gd | 2.54 | 27 | −2.67 (Gd³⁺/Gd) | 1311 |
| Ho | 2.47 | 23.5 | −2.58 (Ho³⁺/Ho) | 1470 |
| Hf | 2.16 | 8 | −2.24 (Hf⁴⁺/Hf) | 2150 |
| La | 2.74 | 37 | −2.85 (La³⁺/La) | 920 |
| Mn | 1.79 | −10.5 | −1.79 (Mn²⁺/Mn) | 1245 |
| Mo | 2.01 | 0.5 | −0.63 (Mo⁴⁺/Mo) | 2617 |
| Nb | 2.08 | 4 | −0.94 (Nb⁵⁺/Nb) | 2468 |
| Nd | 2.64 | 32 | −2.73 (Nd³⁺/Nd) | 1010 |
| Ni | 1.62 | −19 | −0.67 (Ni²⁺/Ni) | 1453 |
| P | 1.23 | −38.5 | −0.74 (P³⁺/P) | 44 |
| Pr | 2.67 | 33.5 | −2.82 (Pr³⁺/Pr) | 935 |
| S | 1.09 | −45.5 | −0.11 (S²⁺/S) | 113 |
| Sc | 2.09 | 4.5 | −2.34 (Sc³⁺/Sc) | 1539 |
| Si | 1.46 | −27 | −1.09 (Si²⁺/Si) | 1410 |
| Sm | 2.59 | 29.5 | −3.42 (Sm²⁺/Sm) | 1072 |
| Ta | 2.09 | 4.5 | −1.07 (Ta⁵⁺/Ta) | 2996 |
| V | 1.92 | −4 | −1.7 (V²⁺/V) | 1890 |
| W | 2.02 | 1 | −0.69 (W²⁺/W) | 3410 |
| Y | 2.27 | 13.5 | −2.6 (Y⁴⁺/Y) | 1523 |
| Yb | 2.4 | 20 | — | 824 |
| Zr | 2.16 | 8 | −1.65 (Zr²⁺/Zr) | 1852 |

¹Standard electrode potentials, specifically, a standard reduction potential measured using a Cl⁻¹/Cl reference electrode.

In an exemplary process, layer 58 is a barrier layer for preventing diffusion from a conductive copper-based material to insulative material 54. In such embodiment, it can be preferred that barrier layer 58 be conductive to provide additional electron flow beyond that provided by the conductive copper-based layer. In such embodiments, it can be preferred that barrier layer 58 have an electrical resistivity of equal to or less than 300 μΩ∘cm.

An exemplary method of forming barrier layer 58 is to sputter deposit layer 58 from a target comprising titanium and one or more elements. The one or more elements can have a standard electrode potential of less than about −1.0V, an atomic radii size difference relative to Ti of at least 8%, and/or melting temperatures greater than or equal to 2400° C. In particular embodiments, the target can consist essentially of the titanium and the one or more elements which have a standard electrode potential of less than about −1.0V, an atomic radii size difference relative to Ti of at least 8%, and/or melting temperatures greater than or equal to 2400° C. Also, the invention encompasses embodiments wherein the target consists of the titanium and the one or more elements having a standard electrode potential of less than about −1.0V, an atomic radii size difference relative to Ti of at least 8%, and/or melting temperatures greater than or equal to 2400° C.

An exemplary target will comprise at least 50 atom % titanium, and from 0.001 atom % to 50 atom % of the one or more elements having a standard electrode potential of less than about −1.0V, an atomic radii size difference relative to Ti of at least 8%, and/or melting temperatures greater than or equal to 2400° C. In other embodiments, the target can comprise at least 90 atom % titanium, and from 0.001 atom % to 10 atom % of the one or more elements which have a standard electrode potential of less than −1.0V, an atomic radii size difference relative to Ti of at least 8%, and/or melting temperatures greater than or equal to 2400° C.

Although previous targets have been produced for different applications (i.e. applications other than for diffusion barriers) having titanium and one or more of Nb, Al, Si, W and Zr; targets of the present invention can differ from the previous targets in that they are used for copper barrier applications and/or the concentration of the Nb, W and Zr can be different in targets of the present invention than in previous targets. For instance, an alloy of the present invention can comprise titanium as the majority element and include an additional element of Nb, W or Zr, excluding the ranges 32-38 atom % and 12-18 atom % for Zr; excluding the range 6-8 atom % for Nb; and excluding the range 35-50 atom % for W. Also, prior art titanium-comprising targets can be utilized for a new method in accordance with methodology of the present invention for forming copper barrier layers.

A target utilized in methodology of the present invention can be sputtered in an atmosphere such that only target materials are deposited in film 58, or alternatively can be sputtered in an atmosphere so that materials from the atmosphere are deposited in barrier layer 58 together with the materials from the target. For instance, the target can be sputtered in an atmosphere comprising a nitrogen-containing component to form a barrier layer 58 that comprises nitrogen in addition to the materials from the target. An exemplary nitrogen-containing component is diatomic nitrogen (N₂). The deposited thin film can be referred to by the stoichiometry TiₓQ_{y}N_{z}, with “Q” being a label for the one or more elements having a standard electrode potential of less than −1.0V, an atomic radii size difference relative to Ti of at least 8%, and/or melting temperatures greater than or equal to 2400° C., that were incorporated into the target. In particular processing, the material TiₓQ_{y}N_{z} will comprise x=0.1 to 0.7, y=0.001 to 0.3, and z=0.1 to 0.6.

Another exemplary method of forming barrier layer 58 is to sputter deposit the layer from a target comprising titanium and one or more elements other than titanium in the presence of both a nitrogen-comprising component and an oxygen-comprising component, to incorporate both nitrogen and oxygen into barrier layer 58. Such processing can form a barrier layer having the stoichiometry TiₓQ_{y}N_{z}O_{w}, with Q again referring to the elements having an atomic radii size difference relative to Ti of at least 8%, elements comprising a standard electrode potential of less than about −1.0V, and/or elements having melting temperatures greater than or equal to 2400° C. The compound TiₓQ_{y}N_{z}O_{w} can comprise, for example, x=0.1 to 0.7, y=0.001 to 0.3, z=0.1 to 0.6, and w=0.0001 to 0.0010. The oxygen-containing component used to form the TiₓQ_{y}N_{z}O_{w}, can be, for example O₂.

There can be advantages to incorporating nitrogen and/or oxygen into a barrier layer 58, in that such incorporation can improve the high-temperature stability of the barrier layer relative to its ability to exclude copper diffusion at high temperatures. The nitrogen and/or oxygen can, for example, disturb a Ti columnar grain structure and thus form a more equi-axed grain structure.

Particular methodology for forming sputtering targets in accordance with the present invention and for depositing thin films from the sputtering targets are described below with reference to examples 1-4.

A barrier layer 58 formed in accordance with the present invention can comprise a mean grain size of less than or equal to 100 nanometers, and in particular processing can preferably comprise a mean grain size of less than or equal to 10 nanometers. More preferably, the barrier layer can comprise a mean grain size of less than 1 nanometer. Further, the barrier layer material can have sufficient stability so that the mean grain size remains less than or equal to 100 nanometers, and in particular embodiments less than or equal to 10 nanometers or 1 nanometer, after the film is exposed to 500° C. for 30 minutes in a vacuum anneal.

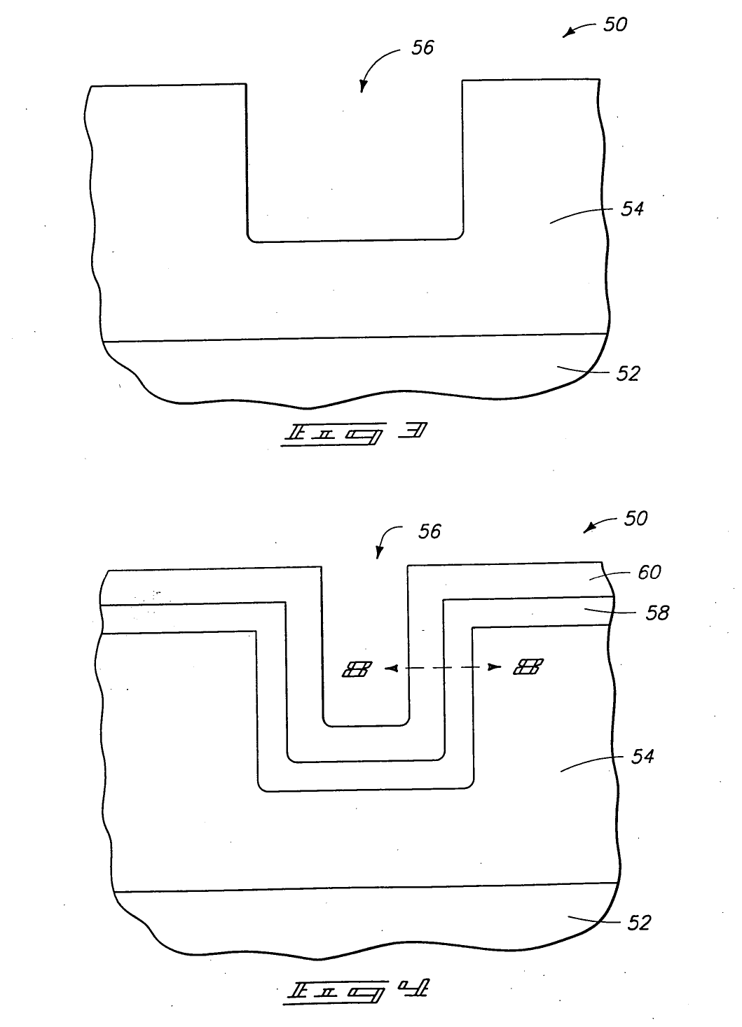

The small mean grain size of the film 58 of the present invention can enable the film to better preclude copper diffusion than can prior art titanium-containing films. Specifically, the prior art titanium-containing films frequently would form large grain sizes at processing above 450° C., and accordingly would have the columnar-type defects described above with reference to FIG. 2. Processing of the present invention can avoid formation of such defects, and accordingly can enable better titanium-containing diffusion layers to be formed than could be formed by prior art processing.

Referring still to FIG. 4, a copper-containing seed layer 60 is formed over barrier layer 58. Copper-containing seed layer 60 can comprise, for example, high purity copper (i.e., copper which is at least 99.995% pure), and can be deposited by, for example, sputter deposition from a high purity copper target.

FIG. 5 illustrates wafer fragment 50 after it has been exposed to chemical-mechanical polishing to remove layers 58 and 60 from over an upper surface of insulative material 54 while leaving materials 58 and 60 within trench 56. FIG. 5 also illustrates processing that can occur specifically when elements having a standard electrode potential of less than −1.0V are in layer 58, and shows that layer 58 has been exposed to thermal processing causing diffusion of the elements having a standard electrode potential less than −1.0V to form a region 62 having a higher concentration of the elements than other regions of material 58. Suitable thermal processing which can cause such migration of the element having a standard electrode potential less than −1.0V includes an anneal at a temperature of about 500° C. for a time of about 30 minutes, under vacuum.

FIG. 7 shows an expanded view of a region of the FIG. 5 wafer fragment 50, and more clearly illustrates the region 62. FIG. 7 also illustrates that another region 64 having an enhanced concentration of the elements with a standard electrode potential of less than −1.0V can be formed adjacent to copper-based layer 60. Region 64 is not shown in FIG. 5 due to limitations of space in the drawing. It is to be understood that region 64 may be effectively eliminated in particular processing of the present invention, depending on the elements incorporated into barrier layer 58.

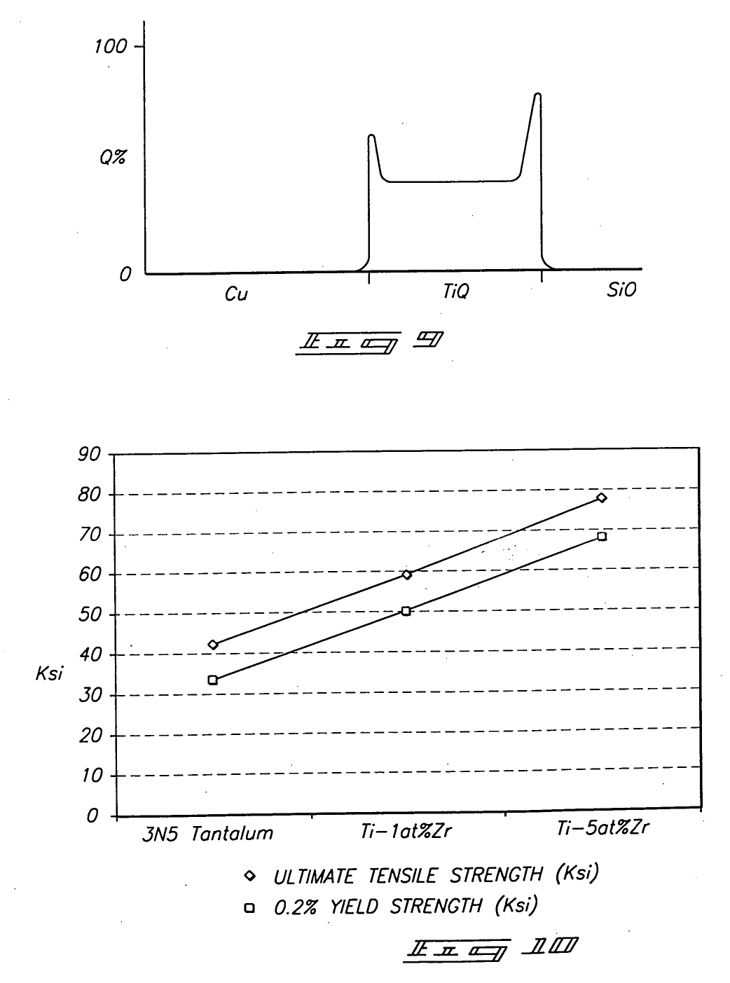

FIGS. 8 and 9 graphically illustrate the aspect of the invention that elements with a standard electrode potential less than −1.0V can migrate within barrier layer 58 during a high-temperature anneal.

Referring first to FIG. 8, such illustrates a graph of a concentration of the elements with a standard electrode potential of less than −1.0V (illustrated as “Q”, and specifically illustrated as a relative percent of “Q”) relative to the copper of layer 60, the TiQ of layer 58 and the SiO of layer 54. It is noted that the TiQ and SiO are not intended to be stoichometric representations of the materials of either barrier layer 58 or insulative material 54, but rather simply identify layers 58 and 64 in the drawing of FIG. 8 (for instance, the material referred to as “SiO” would generally be SiO2). The graph of FIG. 8 is illustrated along an axis shown in FIG. 4, and accordingly corresponds to a processing step prior to the anneal of FIG. 5.

FIG. 9 shows a graph similar to that of FIG. 8, but shows the graph along an axis of FIG. 5, and accordingly is showing relative concentrations after the FIG. 5 anneal. FIG. 9 illustrates that a concentration of Q is increased at an interface between the TiQ layer 58 and SiO layer 54, relative to a concentration throughout a middle region of TiQ. FIG. 9 also illustrates that a concentration of Q can be increased at an interface between copper-based layer 60 and TiQ layer 58.

It is to be understood that even though FIGS. 8 and 9 refer to insulative layer 54 specifically as a SiO layer, such is an exemplary composition for insulative layer 54, and the invention encompasses embodiments wherein layer 54 comprises other insulative materials. It is also to be understood that the relative concentrations of Q shown in FIG. 9 are for illustrative purposes only, and that FIG. 9 is showing a qualitative representation of the concentrations of Q, rather than a quantitative representation.

An advantage of utilizing an element having a standard electrode potential of less than −1.0V is evidenced by FIGS. 7, 8 and 9. Specifically, such elements will tend to diffuse toward the interface regions of barrier layer 58 during an anneal. The element can thus form the regions 62 and 64 of FIG. 7, which can have enhanced copper-barrier aspects relative to the remaining central region of layer 58. Also, the region 62 can have enhanced characteristics for adhering layer 58 to insulative material 54. Accordingly, barrier layers formed in accordance with the present invention can adhere to insulative materials better than barrier layers formed in accordance with the prior art, and can thus alleviate some of the problems associated with prior art barrier layers.

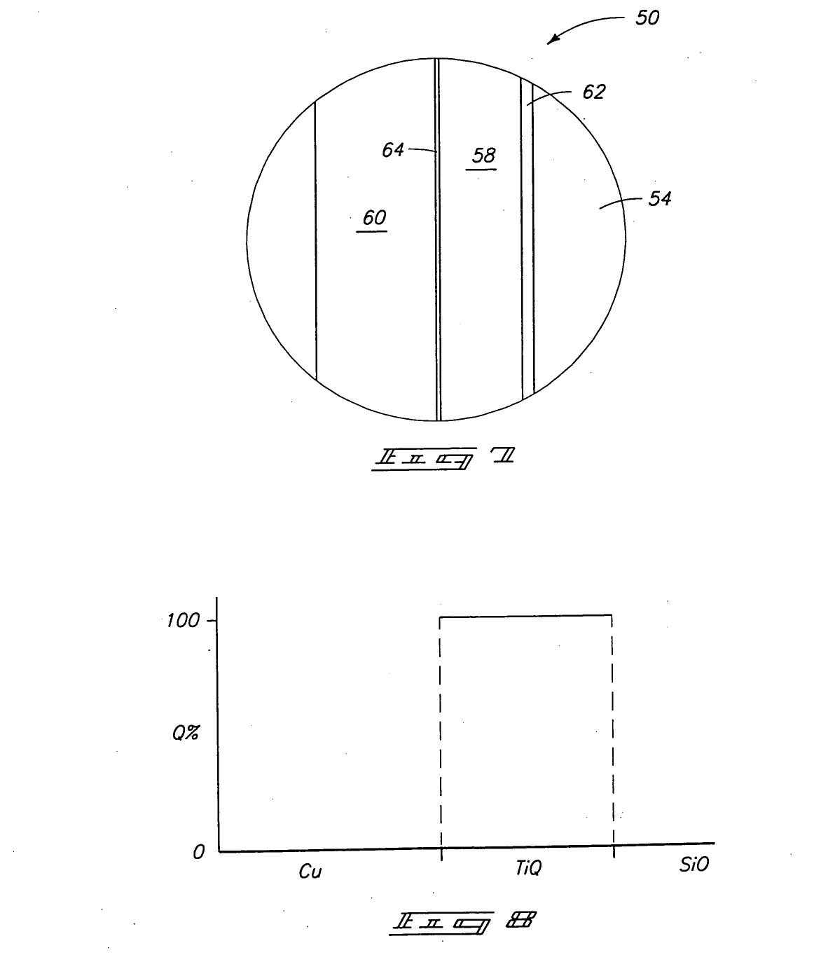

FIG. 6 illustrates wafer fragment 50 at a processing step subsequent to that of FIG. 5, and specifically shows a copper-based material 70 formed within trench 56 (FIG. 5). Copper-based material 70 can be formed by, for example, electrodeposition of copper onto seed layer 60. An advantage of having a conductive barrier layer 58 is evidenced in FIG. 6. Specifically, as trenches become increasingly smaller, the amount of the trench made smaller by barrier layer 58 relative to that consumed by copper material 70 can increase. Accordingly, layers 58, 60 and 70 can be considered a conductive component, with layer 58 having an increasingly larger representative volume as trench sizes become smaller. A reason that layer 58 can have an increasingly larger volume is that there are limits relative to the thickness of layer 58 desired to maintain suitable copper-diffusion barrier characteristics. As the relative volume of layer 58 increases within the conductive component comprising layers 58, 60 and material 70, it can be desired to have good conductive characteristics within material 58 to retain good conductive characteristics within the conductive component.

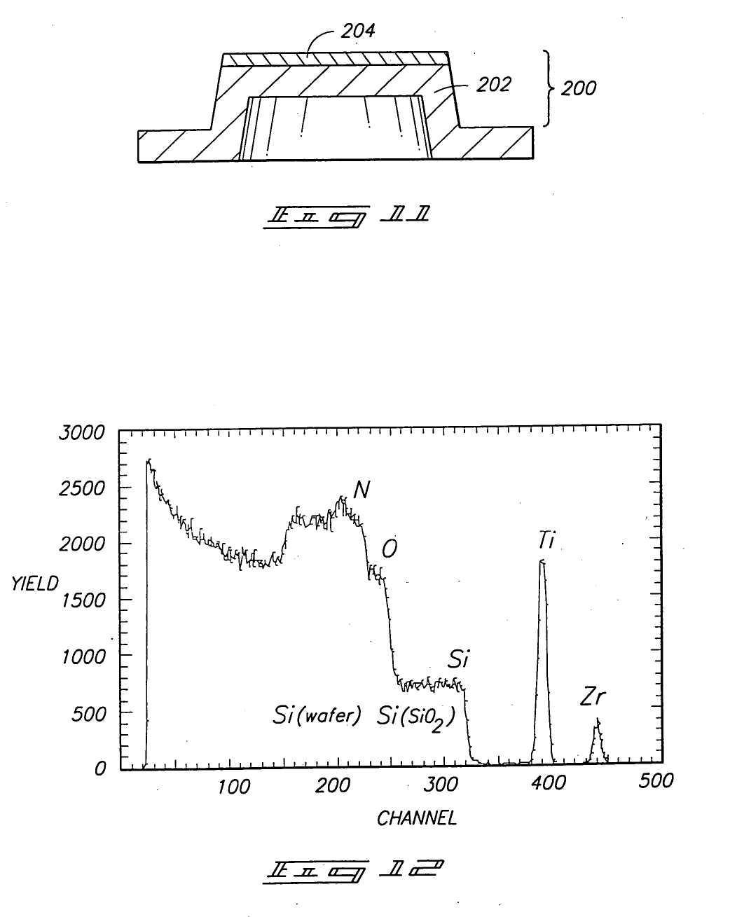

Materials formed in accordance with the present invention can have suitable mechanical properties for utilization in sputtering targets. FIG. 10 shows that materials formed in accordance with the present invention can have mechanical properties equal to, or better than, those of 3N5 tantalum, with the mechanical properties of FIG. 10 being reported in units of Ksi (i.e, 1000 lbs/in²).

### EXAMPLES

The invention is illustrated by, but not limited to, the following examples. The examples describe exemplary methodologies for forming sputtering targets comprising various materials encompassed by the present invention The sputtering targets can have any of numerous geometries, with an exemplary geometry being a so-called ENDURA™ target of the type available from Honeywell Electronics, Inc. An exemplary ENDURA™ target construction 200 is shown in FIG. 11 to comprise a backing plate 202 and a target 204. Target construction 200 is shown in cross-sectional view in FIG. 11, and would typically comprise a circular outer periphery if viewed from the top. Although target construction 200 is shown to comprise the backing plate 202 supporting the target 204, it is to be understood that the invention also encompasses monolithic target constructions (i.e., target constructions in which the entirety of a construction is target material) and other planar target designs.

### Example 1

A TiY target comprises 1.0 at % Y, which is a reactive element with a standard electrode potential of −2.6V and has an atomic radii which is 13.5% larger than that of Ti. A predetermined amount of 3N (99.9%) purity Y was added to a 5N (99.999%) purity Ti during a vacuum skull melt. After a homogeneous alloy is formed, the alloy was cast into a graphite mold to form a billet. The billet was forged and rolled using conventional thermomechanical processes and fabricated into a sputtering target. The Ti-5 at % Y target was reactively sputtered in a N₂/Ar atmosphere with four different values for N₂ flows (0, 5, 10, 15 sccm) and with a total chamber pressure of 4×10⁻³ mTorr. The resulting TiYN thin film had a thickness of approximately 20 nm, an electrical resistivity ranging from approximately 130-300 μΩ•cm, and comprised a very small grain size, which could not be measured by x-ray and could be microcrystalline or amorphous.

### Example 2

A TiTa target comprises 0.65 at % Ta, which is an element with a melting point of 2996° C. and is a reactive element with a standard electrode potential of −1.07V. A predetermined amount of 3N5 (99.95%) purity Ta was added to a 5N (99.999%) purity Ti during a vacuum skull melt. After a homogeneous alloy was formed, the alloy was cast into a graphite mold to form a billet. The billet was forged and rolled using conventional thermomechanical processes, and fabricated into a sputtering target. The Ti-0.65 at % Ta target was reactively sputtered in a N₂/Ar atmosphere with four different values for N₂ flows (0, 5, 10, 15 sccm) and with a total chamber pressure of 4×10⁻³ mTorr. The resulting TiTaN thin film had a thickness of approximately 20 nm, an electrical resistivity ranging from approximately 130-250 μΩ•cm and comprised a very small grain size, which could not be measured by x-ray and could be microcrystalline or amorphous.

### Example 3

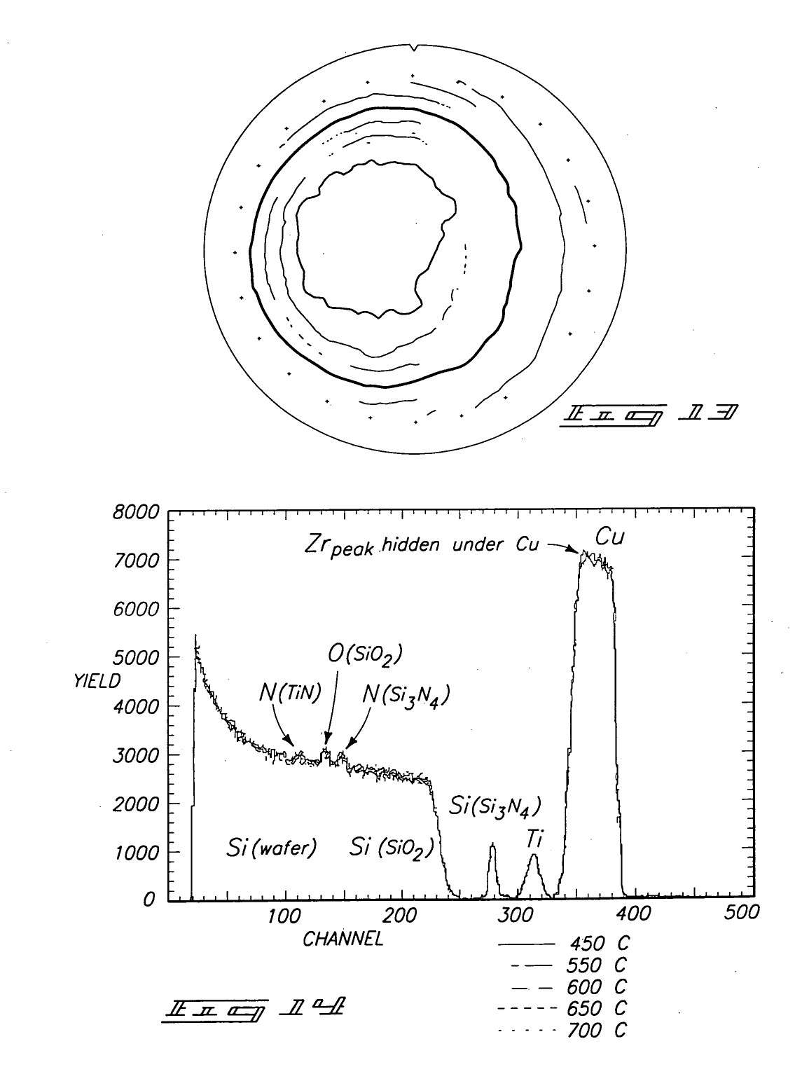

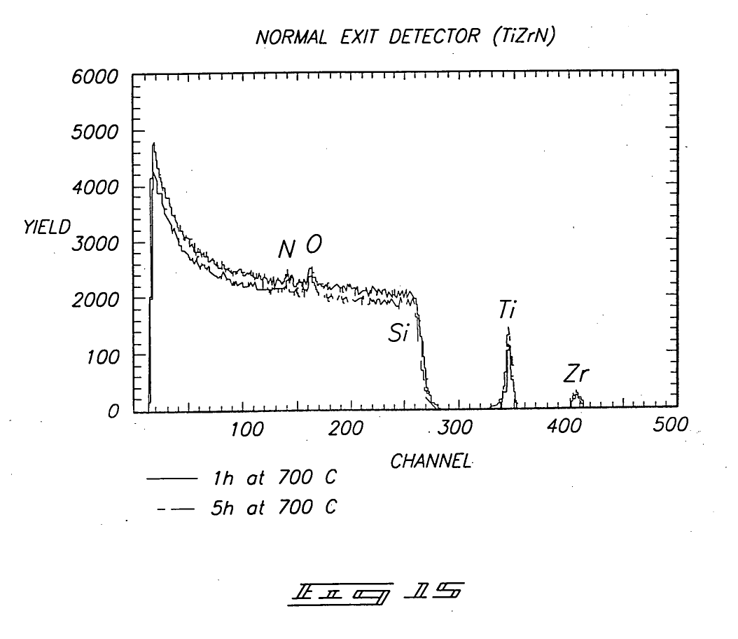

A TiZr target comprises 5.0 at % Zr, which is a reactive element with a standard electrode potential of −1.65V. A predetermined amount of 2N8 (99.8%) purity Zr was added to a 5N (99.999%) purity Ti during a vacuum skull melt. After a homogenous alloy was formed, the alloy was cast into a graphite crucible to form a billet. The billet was forged and rolled using conventional thermomechanical processes and fabricated into a sputtering target. The Ti-5 at % Zr target was reactively sputtered in a N₂/Ar atmosphere. The resulting TiZrN thin film had a thickness of approximately 20 nin and an electrical resistivity of approximately 125 μΩ∘cm. FIG. 13 shows the sheet resistance of the sputtered TiZrN thin film. The TiZrN film had a very small grain size, which could not be measured by x-ray and could be microcrystalline or amorphous, which was stable after vacuum annealing at 700° C. for 5 hours. A 150 nm Cu film was then deposited onto the TiZrN film so that diffusional properties of the TiZrN film could be tested after annealing at high temperature. Results indicate that the TiZrN film had good adhesion to intermetallic dielectrics and wetting characteristics with Cu. The thin film had overall properties that are adequate for a typical Cu/low-k dielectric process. FIG. 12 shows the Rutherford Back-scattering Spectroscopy (RBS) profile of as-deposited Ti_{0.45}Zr_{0.024}N_{0.52}; and Table 2 tabulates various aspects of the data of FIG. 12. FIG. 14 illustrates that there is no apparent diffusion of Cu into the TiZrN layer after vacuum annealing at about 450-700° C. for 1 hour. FIG. 15 shows the RBS profile of the TiZrN film after the Cu layer has been stripped from the wafer. This figure again shows no apparent diffusion of Cu into the TiZrN layer after 5 hours at 700° C.

TABLE 2
RBS determined film composition in atomic percent

| Film | Thickness (nm) | Si | O | Ti | N | Zr |
|---|---|---|---|---|---|---|
| TiZrN | 20 | 0 | 0 | 0.45 | 0.526 | 0.024 |
| SiO₂ | 300 | 0.334 | 0.666 | 0 | 0 | 0 |
| Si | wafer | 1 | 0 | 0 | 0 | 0 |

### Example 4

A TiAl target comprises 1.0 at % Al, which is a reactive element with a standard electrode potential of −1.70V. A predetermined amount of 3N5 (99.95%) purity Al was added to a 5N (99.999%) purity Ti during a vacuum skull melt. After a homogeneous alloy was formed, the alloy was cast into a graphite mold to form a billet. The billet was forged and rolled using conventional thermomechanical processes, and fabricated into a sputtering target. The Ti-1.0 at % Al target was reactively sputtered in a N₂/Ar atmosphere with four different values for N₂ flows (0, 5, 10, 15 sccm) and with a total chamber pressure of 4×10⁻³ mTorr. The resulting TiAlN thin film had a thickness of approximately 20 nm, an electrical resistivity ranging from approximately 130-300 μΩ•cm and comprised a very small grain size, which could not be measured by x-ray and could be microcrystalline or amorphous.

The embodiments described herein are exemplary embodiments, and it is to be understood that the invention encompasses embodiments beyond those specifically described. For instance, the chemical-mechanical polishing described as occurring between the steps of FIGS. 4 and 5, could instead be conducted after electrodeposition of the copper material 70 that is shown in FIG. 6. Also, the anneal described with reference to FIG. 5 as being utilized to form region 62 could be conducted instead after the processing of FIG. 6. Additionally, although various aspects of the invention are described with reference to creating barrier layers to alleviate copper diffusion, it is to be understood that the methodology described herein can be utilized for creating barrier layers that impede or prevent diffusion of metals other than copper; such as, for example, Ag or Al.

1. A sputtering target used for forming a barrier layer relative to a copper-containing material and comprising Ti and one or more alloying elements which have a standard electrode potential of less than about −1.0V.

2. The sputtering target of claim 1 wherein the copper-containing material is a copper-based material.

3. The sputtering target of claim 1 comprising at least one alloying elements which does not have the standard electrode potential of less than about −1.0V.

4. The sputtering target of claim 1 wherein the only alloying elements in the sputtering target are elements having the standard electrode potential of less than about −1.0V.

5. The sputtering target of claim 1 wherein the one or more alloying elements are selected from the group consisting of Be, B, Al, Si, Ca, Sc, V, Cr, Mn, Fe, Sr, Y, Zr, Cs, Ba, La, Hf, Ta, Ce, Pr, Nd, Sm, Gd, Dy, Ho and Er.

6. The sputtering target of claim 1 wherein the one or more alloying elements are selected from the group consisting of Be, Ca, Sr and Ba.

7. The sputtering target of claim 1 wherein the one or more alloying elements comprise Zr.

8. The sputtering target of claim 1 wherein the one or more alloying elements comprise B.

9. The sputtering target of claim 1 wherein the one or more alloying elements comprise Hf.

10. The sputtering target of claim 1 wherein the one or more alloying elements comprise V.

11. The sputtering target of claim 1 wherein the one or more alloying elements comprise Cr.

12. The sputtering target of claim 1 wherein the one or more alloying elements comprise Mn.

13. The sputtering target of claim I wherein the one or more alloying elements comprise Fe.

14. The sputtering target of claim 1 wherein the one or more alloying elements comprise Al.

15. A sputtering target used for forming a barrier layer relative to a Cu-containing material and comprising Ti and one or more alloying elements having at least a 8 percent difference in atomic radii relative to titanium.

16. The sputtering target of claim 15 wherein the one or more alloying elements are selected from the group consisting of Al, Ca, Mn, Fe, Co, Ni, Y, Zr and Hf.

17. The sputtering target of claim 15 wherein the one or more alloying elements comprise Co.

18. The sputtering target of claim 15 wherein the one or more alloying elements comprise Ni.

19. The sputtering target of claim 15 wherein the one or more alloying elements comprise Y.

20. A sputtering target used for forming a barrier layer relative to a Cu-containing material and comprising Ti and one or more alloying elements having at least a 20 percent difference in atomic radii relative to titanium.

21. The sputtering target of claim 20 wherein the one or more alloying elements are selected from the group consisting of Be, B, C, Si, P, S, Cs, Ba, La, Ce, Pr, Nd, Sm, Gd, Dy, Ho, Er and Yb.

22. The sputtering target of claim 20 wherein the one or more alloying elements are selected from the group consisting of Ce, Pr, Nd, Sm, Gd, Dy, Ho, Er and Yb.

23. The sputtering target of claim 20 wherein the one or more alloying elements comprise Ba.

24. The sputtering target of claim 20 wherein the one or more alloying elements comprise La.

25. The sputtering target of claim 20 wherein the one or more alloying elements comprise Yb.

26. A sputtering target used for forming a barrier layer relative to a Cu-containing material and comprising Ti and one or more alloying elements which have a melting temperature of at least about 2400° C.

27. The sputtering target of claim 26 wherein the one or more alloying elements are selected from the group consisting of C, Nb, Mo, Ta and W.

28. The sputtering target of claim 26 wherein the one or more alloying elements comprise Nb.

29. The sputtering target of claim 26 wherein the one or more alloying elements comprise Mo.

30. The sputtering target of claim 26 wherein the one or more alloying elements comprise Ta.

31. The sputtering target of claim 26 wherein the one or more alloying elements comprise W.

32. A sputtering target consisting: essentially of Ti and Zr; and containing less than 12 atomic percent Zr.

33. The sputtering target of claim 32 containing less than 8 atomic percent Zr.

34. The sputtering target of claim 32 containing less than 6 atomic percent Zr.

35. The sputtering target of claim 32 containing less than 2 atomic percent Zr.

36. The sputtering target of claim 32 containing from 2 atomic percent to less than 12 atomic percent Zr.

37. A sputtering target comprising Ti and one or more alloying elements which have a standard electrode potential of less than about −1.0V; said sputtering target not including binary alloys of TiAl and TiSi; and further not including binary alloys of TiZr in which Zr is present in the range of 12-18 atom % or in the range of 32-38 atom %.

38. The sputtering target of claim 37 wherein the one or more alloying elements are selected from the group consisting of Be, B, Ca, Sc, V, Cr, Mn, Fe, Sr, Y, Cs, Ba, La, Hf, Ta, Ce, Pr, Nd, Sm, Gd, Dy, Ho and Er.

39. The sputtering target of claim 37 wherein the one or more alloying elements are selected from the group consisting of Be, Ca, Sr and Ba.

40. The sputtering target of claim 37 wherein the one or more alloying elements comprise B.

41. The sputtering target of claim 37 wherein the one or more alloying elements comprise Hf.

42. The sputtering target of claim 37 wherein the one or more alloying elements comprise V.

43. The sputtering target of claim 37 wherein the one or more alloying elements comprise Cr.

44. The sputtering target of claim 37 wherein the one or more alloying elements comprise Mn.

45. The sputtering target of claim 37 wherein the one or more alloying elements comprise Fe.

46. A sputtering target comprising Ti and one or more alloying elements having at least a 8 percent difference in atomic radii relative to titanium; said sputtering target not including binary complexes of Ti and alloying elements selected from the group consisting of Al and Si; said sputtering target also not including binary complexes of Ti and Zr in which Zr is present in the range of 12-18 atom % or in the range of 32-38 atom %.

47. The sputtering target of claim 46 wherein the one or more alloying elements are selected from the group consisting of Ca, Mn, Fe, Co, Ni, Y, and Hf.

48. The sputtering target of claim 46 wherein the one or more alloying elements comprise Y.

49. The sputtering target of claim 46 wherein the one or more alloying elements comprise Co.

50. The sputtering target of claim 46 wherein the one or more alloying elements comprise Ni.

51. The sputtering target of claim 46 wherein the one or more alloying elements have a difference in atomic radii of at least 20% relative to Ti.

52. The sputtering target of claim 51 wherein the one or more alloying elements are selected from the group consisting of Be, B, C, P, S, Cs, Ba, La, Ce, Pr, Nd, Sm, Gd, Dy, Ho, Er and Yb.

53. The 'sputtering target of claim 51 wherein the one or more alloying elements are selected from the group consisting of Ce, Pr, Nd, Sm, Gd, Dy, Ho, Er and Yb.

54. The sputtering target of claim 51 wherein the one or more alloying elements comprise Ba.

55. The sputtering target of claim 51 wherein the one or more alloying elements comprise La.

56. The sputtering target of claim 51 wherein the one or more alloying elements comprise Yb.

57. A sputtering target comprising Ti and one or more alloying elements which have a melting temperature of at least about 2400° C.; said sputtering target not including binary alloys of Ti and W in which W is the range of 35-50 atom %; said sputtering target also not including binary alloys of Ti and Nb in which Nb is the range of 6-8 atom %.

58. The sputtering target of claim 57 wherein the one or more alloying elements are selected from the group consisting of C, Mo, and Ta.

59. The sputtering target of claim 57 wherein the one or more alloying elements comprise Mo.

60. The sputtering target of claim 57 wherein the one or more alloying elements comprise Ta.

61. A sputtering target used for forming a barrier layer relative to a silver-containing material and comprising Ti and one or more alloying elements having at least one of: (1) a standard electrode potential of less than about −1.0V; (2) a melting temperature of at least about 2400° C.; or (3) at least a 8 percent difference in atomic radii relative to titanium.

62. The sputtering target of claim 61 wherein the one or more alloying elements comprise Zr.

63. A sputtering target used for forming a barrier layer relative to an aluminum-containing material and comprising Ti and one or more alloying elements having at least one of: (1) a standard electrode potential of less than about −1.0V; (2) a melting temperature of at least about 2400° C.; or (3) at least a 8 percent difference in atomic radii relative to titanium.

64. The sputtering target of claim 63 wherein the one or more alloying elements comprise Zr.

65. A means for forming a Cu barrier layer by sputter-depositing a film from a target comprising Ti and one. or more alloying elements selected from the group consisting of Be, B, Al, Si, Ca, Sc, V, Cr, Mn, Fe, Sr, Y, Zr, Cs, Ba, La, Hf, Ta, Ce, Pr, Nd, Sm, Gd, Dy, Ho and Er.

66. The means of claim 65 wherein the one or more alloying elements comprise Zr.

67. The means of claim 65 wherein the one or more alloying elements comprise V.

68. The means of claim 65 wherein the one or more alloying elements comprise Cr.

69. The means of claim 65 wherein the one or more alloying elements comprise Mn.

70. The means of claim 65 wherein the one or more alloying elements comprise Fe.

71. The means of claim 65 wherein the one or more alloying elements comprise Al.

72. A method of inhibiting copper diffusion into a substrate, comprising:
forming a first layer comprising Ti and one or more alloying elements over the substrate, the one or more alloying elements having a difference in atomic radii relative to Ti of at least 8%; and
forming a copper-containing layer over the first layer; the first layer inhibiting copper diffusion from the copper-containing layer to the substrate.

73. The method of claim 72 wherein the copper-containing layer is a copper-based layer.

74. The method of claim 72 wherein the one or more alloying elements are selected from the group consisting of Al, Ca, Mn, Fe, Co, Ni, Y, Zr and Hf.

75. The method of claim 72 wherein the one or more alloying elements comprise Y.

76. The method of claim 72 wherein the one or more alloying elements have a difference in atomic radii of at least 20% relative to Ti.

77. The method of claim 76 wherein the one or more alloying elements are selected from the group consisting of Be, B, C, Si, P, S, Cs, Ba, La, Ce, Pr, Nd, Sm, Gd, Dy, Ho, Er and Yb.

78. The method of claim 76 wherein the one or more alloying elements comprise Ba.

79. The method of claim 76 wherein the one or more alloying elements comprise La.

80. The method of claim 76 wherein the one or more alloying elements comprise Yb.

81. A method of inhibiting copper diffusion into a substrate, comprising:
forming a first layer comprising Ti and one or more alloying elements which have a standard electrode potential of less than about −1.0V over the substrate; and
forming a copper-containing layer over the first layer; the first layer inhibiting copper diffusion from the copper-containing layer to the substrate.

82. The method of claim 81 wherein the one or more alloying elements are selected from the group consisting of Be, B, Al, Si, Ca, Sc, V, Cr, Mn, Fe, Sr, Y, Zr, Cs, Ba, La, Hf, Ta, Ce, Pr, Nd, Sm, Gd, Dy, Ho and Er.

83. The method of claim 81 wherein the layer consists essentially of the Ti and the one or more alloying elements.

84. The method of claim 81 wherein the layer consists of the Ti and the one or more alloying elements.

85. The method of claim 81 wherein the one or more alloying elements comprise Zr.

86. The method of claim 81 wherein the one or more alloying elements comprise V.

87. The method of claim 81 wherein the one or more alloying elements comprise Cr.

88. The method of claim 81 wherein the one or more alloying elements comprise Mn.

89. The method of claim 81 wherein the one or more alloying elements comprise Fe.

90. The method of claim 81 wherein the one or more alloying elements comprise Al.

91. The method of claim 81 wherein the first layer is formed by sputter deposition from a target comprising. the Ti and the one or more alloying elements which have a standard electrode potential of less than about −1.0V.

92. A thin film of TiₓQ_{y}N_{z} inhibiting copper diffusion from a copper-containing material and formed by sputtering a sputtering target in a nitrogen atmosphere, wherein “Q” is a label for said one or more alloying elements; said target comprising Ti and one or more alloying elements which have a standard electrode potential of less than about −1.0V.

93. The thin film of claim 92 wherein x=0.1-0.7, y=0.001-0.3, and z=0.1-0.6.

94. The thin film of claim 92 having a thickness of from about 2 nm to about 50 nm.

95. The thin film of claim 92 having a thickness of from about 2 nm to about 20 nm.

96. The thin film of claim 92 further comprising an electrical resistivity of equal to or less than 300 μΩ•cm.

97. The TiₓQ_{y}N_{z} thin film of claim 92 used as a Cu barrier layer in a microelectronic device.

98. The thin film of claim 92 further comprising a mean grain size of equal to or less than 100 nm, the mean grain size remaining equal to or less than 100 nm after the thin film is exposed to a temperature of at least about 500° C. for a time of at least about 30 minutes in a vacuum anneal.

99. The thin film of claim 92 further comprising a mean grain size of equal to or smaller than 10 nm, the mean grain size remaining equal to or less than 10 nm after the thin film is exposed to a temperature of at least about 500° C. for a time of at least about 30 minutes in a vacuum anneal.

100. The thin film of claim 92 further comprising a mean grain size of equal to or smaller than 1 nm, the mean grain size remaining equal to or less than 1 nm after the thin film is exposed to a temperature of at least about 500° C. for a time of at least about 30 minutes in a vacuum anneal.

101. A thin film of TiₓQ_{y}N_{z}O_{w} inhibiting copper diffusion from a copper-containing material and formed by sputtering a sputtering target in the presence of a nitrogen-containing gas and an oxygen-containing gas, wherein “Q” is a label for said one or more alloying elements; said target comprising Ti and one or more alloying elements which have a standard electrode potential of less than about −1.0V.

102. The thin film of claim 101 wherein x=0.1-0.7, y=0.001-0.3, z=0.1-0.6, and w=0.0001-0.0010.

103. The thin film of claim 101 having a thickness of from about 2 nm to about 50 nm.

104. The thin film of claim 101 having a thickness of from about 2 nm to about 20 nm.

105. The thin film of claim 101 further comprising an electrical resistivity of equal to or lower than 300 μΩ•cm.

106. The thin film of claim 101 further comprising a mean grain size of equal to or less than 100 nm, the mean grain size remaining equal to or less than 100 nm after the thin film is exposed to a temperature of at least about 500° C. for a time of at least about 30 minutes in a vacuum anneal.

107. The thin film of claim 101 further comprising a mean grain size of equal to or smaller than 10 nm, the mean grain size remaining equal to or less than 10 nm after the thin film is exposed to a temperature of at least about 500° C. for a time of at least about 30 minutes in a vacuum anneal.

108. The thin film of claim 101 further comprising a mean grain size of equal to or smaller than 1 nm, the mean grain size remaining equal to or less than 1 nm after the thin film is exposed to a temperature of at least about 500° C. for a time of at least about 30 minutes in a vacuum anneal.

109. The TiₓQ_{y}N_{z}O_{w} thin film of claim 101 used as a Cu barrier layer in a microelectronic device.

110. A thin film of TiₓQ_{y}N_{z} inhibiting copper diffusion from a copper-containing material and formed by sputtering a sputtering target in a nitrogen atmosphere, wherein “Q” is a label for said one or more alloying elements; said target comprising Ti and one or more alloying elements which have a melting temperature of at least about 2400° C.

111. The thin film of claim 110 wherein x=0.1-0.7, y=0.001-0.3, and z=0.1-0.6.

112. The thin film of claim 110 having a thickness of from about 2 nm to about 50 nm.

113. The thin film of claim 110 having a thickness of from about 2 nm to about 20 nm.

114. The thin film of claim 110 further comprising an electrical resistivity of equal to or less than 300 μΩ•cm.

115. The TiₓQ_{y}N_{z} thin film of claim 110 used as a Cu barrier layer in a microelectronic device.

116. The thin film of claim 110 further comprising a mean grain size of equal to or less than 100 nm, the mean grain size remaining equal to or less than 100 nm after the thin film is exposed to a temperature of at least about 500° C. for a time of at least about 30 minutes in a vacuum anneal.

117. The thin film of claim 110 further comprising a mean grain size of equal to or smaller than 10 nm, the mean grain size remaining equal to or less than 10 nm after the thin film is exposed to a temperature of at least about 500° C. for a time of at least about 30 minutes in a vacuum anneal.

118. The thin film of claim 110 further comprising a mean grain size of equal to or smaller than 1 nm, the mean grain size remaining equal to or less than 1 nm after the thin film is exposed to a temperature of at least about 500° C. for a time of at least about 30 minutes in a vacuum anneal.

119. A thin film of TiₓQ_{y}N_{z}O_{w} inhibiting copper diffusion from a copper-containing material and formed by sputtering a sputtering target in the presence of a nitrogen-containing gas and an oxygen-containing gas, wherein “Q” is a label for said one or more alloying elements; said target comprising Ti and one or more alloying elements which have a melting temperature of at least about 2400° C.

120. The thin film of claim 119 wherein x=0.1-0.7, y=0.001-0.3, z=0.1-0.6, and w=0.0001-0.0010.

121. The thin film of claim 119 having a thickness of from about 2 nm to about 50 nm.

122. The thin film of claim 119 having a thickness of from about 2 nm to about 20 nm.

123. The thin film of claim 119 further comprising an electrical resistivity of equal to or lower than 300 μΩ•cm.

124. The thin film of claim 119 further comprising a mean grain size of equal to or less than 100 nm, the mean grain size remaining equal to or less than 100 nm after the thin film is exposed to a temperature of at least about 500° C. for a time of at least about 30 minutes in a vacuum anneal.

125. The thin film of claim 119 further comprising a mean grain size of equal to or smaller than 10 nm, the mean grain size remaining equal to or less than 10 nm after the thin film is exposed to a temperature of at least about 500° C. for a time of at least about 30 minutes in a vacuum anneal.

126. The thin film of claim 119 further comprising a mean grain size of equal to or smaller than 1 nm, the mean grain size remaining equal to or less than 1 nm after the thin film is exposed to a temperature of at least about 500° C. for a time of at least about 30 minutes in a vacuum anneal.

127. The thin film of claim 119 used as a Cu barrier layer in a microelectronic device.

128. A thin film of TiₓQ_{y}N_{z} inhibiting copper-diffusion from a copper-containing material and formed by sputtering a sputtering target in a nitrogen atmosphere, wherein “Q” is a label for said one or more alloying elements; said target comprising Ti and one or more alloying elements having at least a 8 percent difference in atomic radii relative to titanium.

129. The thin film of claim 128 wherein x=0.1-0.7, y=0.001-0.3, and z=0.1-0.6.

130. The thin film of claim 128 having a thickness of from about 2 nm to about 50 nm.

131. The thin film of claim 128 having a thickness of from about 2 nm to about 20 nm.

132. The thin film of claim 128 further comprising an electrical resistivity of equal to or less than 300 μΩ•cm.

133. The thin film of claim 128 used as a Cu barrier layer in a microelectronic device.

134. the thin film of claim 128 further comprising a mean grain size of equal to or less than 100 nm, the mean grain size remaining equal to or less than 100 nm after the thin film is exposed to a temperature of at least about 500° C. for a time of at least about 30 minutes in a vacuum anneal.

135. The thin film of claim 128 further comprising a mean grain size of equal to or smaller than 10 nm, the mean grain size remaining equal to or less than 10 nm after the thin film is exposed to a temperature of at least about 500° C. for a time of at least about 30 minutes in a vacuum anneal.

136. The thin film of claim 128 further comprising a mean grain size of equal to or smaller than 1 nm, the mean grain size remaining equal to or less than 1 nm after the thin film is exposed to a temperature of at least about 500° C. for a time of at least about 30 minutes in a vacuum anneal.

137. A thin film of TiₓQ_{y}N_{z}O_{w} inhibiting copper diffusion from a copper-containing material and formed by sputtering a sputtering target in the presence of a nitrogen-containing gas and an oxygen-containing gas, wherein “Q” is a label for said one or more alloying elements; said target comprising Ti and one or more alloying elements having at least a 8 percent difference in atomic radii relative to titanium.

138. The thin film of claim 137 wherein x=0.1-0.7, y=0.001-0.3, z=0.1-0.6, and w=0.0001-0.0010.

139. The thin film of claim 137 having a thickness of from about 2 nm to about 50 nm.

140. The thin film of claim 137 having a thickness of from about 2 nm to about 20 nm.

141. The thin film of claim 137 further comprising an electrical resistivity of equal to or lower than 300 μΩ•cm.

142. The thin film of claim 137 further comprising a mean grain size of equal to or less than 100 nm, the mean grain size remaining equal to or less than 100 nm after the thin film is exposed to a temperature of at least about 500° C. for a time of at least about 30 minutes in a vacuum anneal.

143. The thin film of claim 137 further comprising a mean grain size of equal to or smaller than 10 nm, the mean grain size remaining equal to or less than 10 nm after the thin film is exposed to a temperature of at least about 500° C. for a time of at least about 30 minutes in a vacuum anneal.

144. The thin film of claim 137 further comprising a mean grain size of equal to or smaller than 1 nm, the mean grain size remaining equal to or less than 1 nm after the thin film is exposed to a temperature of at least about 500° C. for a time of at least about 30 minutes in a vacuum anneal.

145. The TiₓQ_{y}N_{z}O_{w} thin film of claim 137 used as a Cu barrier layer in a microelectronic device.

146. A semiconductor construction, comprising
a semiconductor substrate;
a material supported by the semiconductor substrate, and into which diffusion of a metal is to be alleviated;
a mass over the material and comprising the metal;
a intervening layer comprising Ti and one or more alloying elements; the intervening layer being between the mass and the material into which diffusion of the metal is to be alleviated; the one or more alloying elements at having least one of: (1) a standard electrode potential of less than about −1.0V; (2) a melting temperature of at least about 2400° C.; or (3) at least a 8 percent difference in atomic radii relative to titanium; and
the intervening layer alleviating diffusion of the metal from the mass to the material relative to an amount of diffusion that would occur without the intervening layer.

147. The construction of claim 146 wherein the metal for which diffusion is to be alleviated is copper.

148. The construction of claim 146 wherein the one or more alloying elements are selected from the group consisting of Be, B, Al, Si, Ca, Sc, V, Cr, Mn, Fe, Sr, Y, Zr, Cs, Ba, La, Hf, Ta, Ce, Pr, Nd, Sm, Gd, Dy, Ho and Er.

149. The construction of claim 146 wherein the one or more alloying elements comprise Zr.

150. The construction of claim 146 wherein the one or more alloying elements comprise V.

151. The construction of claim 146 wherein the one or more alloying elements comprise Cr.

152. The construction of claim 146 wherein the one or more alloying elements comprise Mn.

153. The construction of claim 146 wherein the one or more alloying elements comprise Al.

154. The construction of claim 146 wherein the one or more alloying elements comprise B.

155. The construction of claim 146 wherein the one or more alloying elements comprise Nb.

156. The construction of claim 146 wherein the one or more alloying elements comprise Mo.

157. The construction of claim 146 wherein the one or more alloying elements comprise Hf.

158. The construction of claim 146 wherein the one or more alloying elements comprise Ta.

159. The construction of claim 146 wherein the one or more alloying elements comprise W.

160. The construction of claim 146 wherein the one or more alloying elements comprise Y.

161. The construction of claim 146 wherein the one or more alloying elements comprise Co.

162. The construction of claim 146 wherein the one or more alloying elements comprise Ni.

163. The construction of claim 146 wherein the one or more alloying elements comprise Ba.

164. The construction of claim 146 wherein the one or more alloying elements comprise La.

165. The construction of claim 146 wherein the one or more alloying elements comprise Yb.

166. The construction of claim 146 wherein the metal for which diffusion is to be alleviated is copper; and wherein the material into which copper diffusion is to be alleviated is an electrically insulative material.

167. The construction of claim 146 wherein the metal for which diffusion is to be alleviated is copper; and wherein the material into which copper diffusion is to be alleviated comprises silicon dioxide.

168. The construction of claim 146 wherein the metal for which diffusion is to be alleviated is copper; and wherein the material into which copper diffusion is to be alleviated comprises BPSG.

169. The construction of claim 146 wherein the metal for which diffusion is to be alleviated is copper; and wherein the material into which copper diffusion is to be alleviated comprises fluorinated silicon dioxide with a dielectric constant less than or equal to 3.7.

170. The construction of claim 146 wherein the metal for which diffusion is to be alleviated is copper; and wherein the material into which copper diffusion is to be alleviated comprises an insulative material with a dielectric constant less than or equal to 3.7.
